(19) United States
(12) Patent Application Publication
(10) Pub. No.: US 2026/0334337 A1
(43) Pub. Date: Oct. 22, 2026

(54) LOW-SKEW HIGH-SPEED IO BALL PATTERN FOR HPC

(71) Applicant: Hewlett Packard Enterprise Development LP, Spring, TX (US)

(72) Inventors: Roger J. Gravrok, Eau Claire, WI (US); Shawn Robert Utz, Kent, WA (US); Chi Kim Sides, Spring, TX (US); Jeffrey Scott Conger, Eau Claire, WI (US)

(21) Appl. No.: 19/184,938

(22) Filed: Apr. 21, 2025

(51) Int. Cl. H01L 23/498

(52) U.S. Cl. CPC H10W 90/701

(57) ABSTRACT

One aspect of the instant disclosure provides a ball grid array for an integrated circuit (IC) package. The ball grid array may include a first subset of solder balls, arranged in a first hexagonal grid pattern, comprising at least a first pair of signal balls to couple to a first pair of differential signal traces on a printed circuit board. The first pair of signal balls may be positioned in alternate rows that are separated by a row of solder balls of the first hexagonal grid pattern and aligned in parallel to an adjacent first edge of the IC package, via which the first pair of differential signal traces escape the IC package with substantially equal trace lengths.

### STATEMENT OF GOVERNMENT-FUNDED RESEARCH

This invention was made with Government support under Contract Number H98230-23-C-0350 awarded by the Maryland Procurement Office. The Government has certain rights in this invention.

### BACKGROUND

### Field

This disclosure relates to a ball grid array (BGA) packaging designed for high-performance computing (HPC) systems.

### Related Art

High-performance computing (HPC) systems frequently rely on high-density Application-Specific Integrated Circuits (ASICs) to overcome key challenges such as performance scalability, energy efficiency, and physical space limitations. Such specialized Integrated Circuit (IC) chips are designed to optimize computational throughput while minimizing power consumption and infrastructure footprint, making them indispensable for modern HPC workloads like AI training, scientific simulations, and big data analytics.

To integrate these high-density ASICs into HPC systems, the chips are typically housed in protective packages mounted onto printed circuit boards (PCBs). Compared with traditional pin grid array (PGA) packages, ball grid array (BGA) packages offer significantly higher input/output (I/O) density due to their scalable interconnect capacity and fine-pitch compatibility. BGA packages can accommodate hundreds to thousands of solder balls with ball pitches as small as 0.5 mm, making them ideal for high-performance applications.

The solder balls in BGA packages can be arranged in various grid configurations, such as rectangular/square, face-centered, or hexagonal patterns. Hexagonal patterns achieve the highest ball density, providing ~15% greater density compared with square arrangements. However, when implemented on square or rectangular packages, the staggered alignment of adjacent rows in hexagonal configurations introduces timing skew across signal traces escaping the BGA package, posing challenges for signal integrity in high-speed applications.

### BRIEF DESCRIPTION OF THE FIGURES

FIG. 1A illustrates example signal ball patterns on a ball grid array (BGA) package with a hexagonal grid pattern, according to one aspect of the instant disclosure.

FIG. 1B illustrates the cross-sectional view of an example BGA package, according to one aspect of the instant disclosure.

FIG. 2A shows the partial view of an example BGA-packaged device with multiple ports, according to one aspect of the instant disclosure.

FIG. 2B illustrates the partial view of an example printed circuit board (PCB) for mounting the BGA-packaged device, according to one aspect of the instant disclosure.

FIGS. 3A and 3B illustrate the relative orientations of hexagonal solder ball arrays along adjacent edges of a square/rectangular BGA package, according to one aspect of the instant disclosure.

FIG. 4A illustrates an example solder ball arrangement for a BGA package, according to one aspect of the instant application.

FIG. 4B illustrates an example solder ball arrangement for a BGA package, according to one aspect of the instant application.

FIG. 5 illustrates an example fabrication process of a BGA package, according to one aspect of the instant application.

In the figures, like reference numerals refer to the same figure elements.

### DETAILED DESCRIPTION

Differential signal skew presents a challenge to signal integrity and channel reliability in high-speed I/O. With interfaces operating at 224 Gbps, intra-pair skew must be maintained below four picoseconds to ensure robust data transmission. Such a stringent requirement demands near-perfect length matching of differential signal traces escaping from BGA packages. However, the hexagonal grid configuration adopted by a BGA package housing high-density, high-speed I/O ASIC chips may introduce inherent challenges. More particularly, the non-symmetrical layout can exacerbate timing discrepancies across multiple high-speed channels, and the staggered arrangement of solder balls in a hexagonal grid creates asymmetric breakout paths, leading to gross length mismatches (e.g., ±50-100 μm) between differential pairs escaping different package edges.

In BGA packages with hexagonal patterns, the spatial arrangement of signal balls (i.e., solder balls coupled to signal traces) directly affects the escape routing geometry of differential signal traces on the printed circuit board (PCB). Conventional design methodologies typically assign differential signal pairs to BGA balls in adjacent rows with uneven distances to the package edge from which the differential signal traces escape. Such an arrangement introduces inherent skew due to the unequal trace lengths and asymmetrical routing paths. This structural limitation compromises timing alignment between differential signal pairs, degrading system performance in applications requiring tight skew tolerances (e.g., high-speed I/O interfaces). To reduce the timing skew, according to some aspects of the instant disclosure, the differential signal pairs may be assigned to BGA balls on alternate rows with a substantially equal distance to the package edge from which the differential signal traces escape. The BGA balls coupled with the differential signal traces are referred to as signal balls. The assignment of the signal balls may affect the performance of the high-speed differential signals.

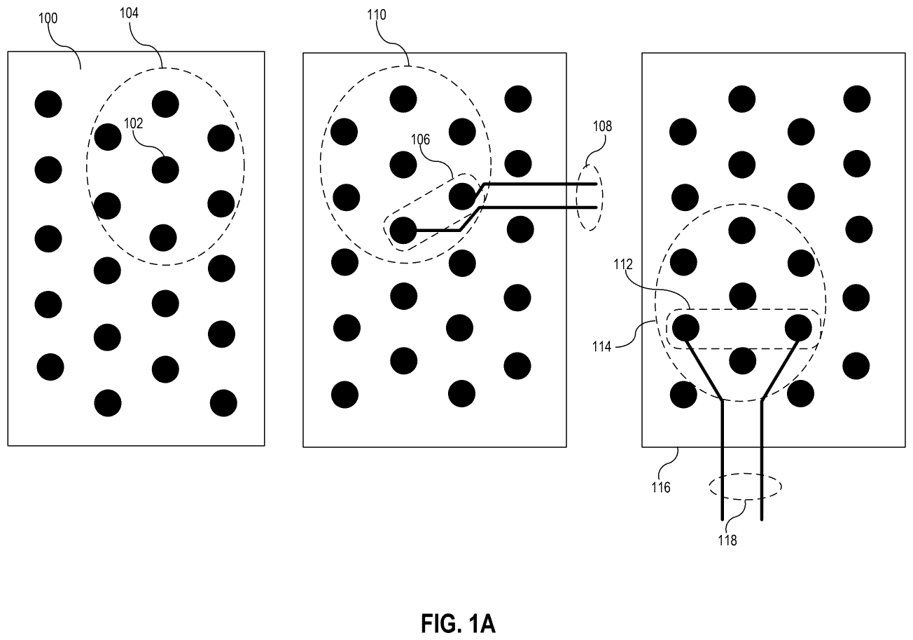

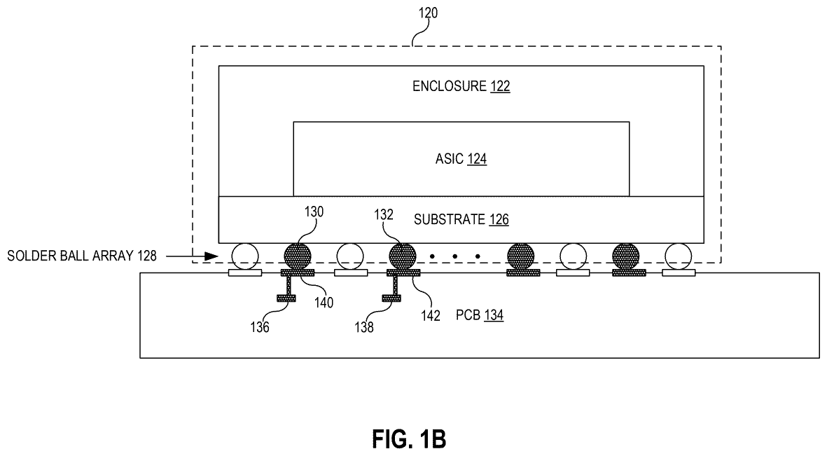

FIG. 1A illustrates example signal ball patterns on a ball grid array (BGA) package with a hexagonal grid pattern, according to one aspect of the instant disclosure. The left portion of FIG. 1A shows the bottom of a BGA package 100, which includes a plurality of solder balls arranged in a hexagonal grid configuration where each interior ball (e.g., ball 102) is equidistant to six neighboring balls, forming a tight hexagonal cluster (e.g., cluster 104). This arrangement can increase the ball density but introduces asymmetrical properties when implemented on square or rectangular packages.

The middle portion of FIG. 1A shows a conventional scheme for selecting a signal ball pair 106 and the corresponding escape routing paths 108. Conventional signal ball pair 106 includes solder balls in adjacent rows (and adjacent columns). It should be noted that the terms “row” and “column” are used relatively and may be interchangeable depending on the context or orientation of a reference frame. Similarly, the terms “horizontal” and “vertical” are used relatively and may be interchangeable depending on the orientation of a reference. In the context of this disclosure, the orientation is defined in relation to the accompanying drawings, where horizontal refers to the left-to-right (or right-to-left) direction and vertical refers to the upward-downward (or downward-upward) direction. In the example depicted in FIG. 1, solder balls aligned horizontally are referred to as being in the same row, while those aligned vertically are referred to as being in the same column. As can be seen in FIG. 1, solder balls in pair 106 are arranged diagonally with respect to all edges of rectangular BGA package 100, causing them to have different distances to an edge. As a result, escape routing paths 108 would have different lengths. In this conventional arrangement, signal balls in pair 106 are on adjacent vertices of a hexagon 110, forming an edge of the hexagon. This arrangement may introduce inherent skew between the different traces of a signal pair.

The right portion of FIG. 1A illustrates a signal ball pair 112 selected in accordance with one aspect of the present disclosure. Specifically, the solder balls in pair 112 are positioned within the same row but belong to alternate, non-adjacent columns. In this novel arrangement, signal balls in pair 112 occupy alternate vertices of a hexagon 114, along one of its shorter diagonals.

Because the solder balls in pair 112 are in the same row, they are equidistant to a package edge 116 parallel to that row. The variation in the distance may be attributed to fabrication tolerances, which are typically very small. For example, the typical position tolerance of solder balls in a BGA package is less than 100 μm, meaning that the difference in the distance from each solder ball in pair 112 to package edge 116 may be less than 100 μm. Package edge 116 may serve as the designated escape edge, enabling symmetric routing paths 118 for the differential pair. As illustrated in FIG. 1A, traces from pair 112 exit the BGA package through the horizontal edge 116 aligned with the axis of the pair, ensuring matched trace lengths and minimizing intra-pair signal skew. The axis of a pair of solder balls can be a straight line connecting centers of the pair.

FIG. 1B illustrates the cross-sectional view of an example BGA package, according to one aspect of the instant disclosure. In FIG. 1B, a BGA package 120 includes an enclosure 122, an ASIC chip 124, a substrate 126, and a solder ball array 128. Enclosure 122 can be made of plastics and can protect the enclosed chips from environmental factors. According to some aspects, ASIC chip 124 may include a high-speed switch chip, a high-speed NIC chip, or an ASIC chip for any other high-speed application.

Substrate 126 may be made of various types of material, such as plastic, resin, ceramic materials, or any other suitable substrate material. ASIC chip 124 may be attached to the substrate by a separate set of solder balls or solder bumps (not shown in FIG. 1B).

Solder ball array 128 includes a plurality of solder balls arranged in a grid pattern. These solder balls are electrically connected to (e.g., via routing traces within BGA package 120) circuit components in ASIC chip 124. In one example, ASIC chip 124 may include a switch ASIC with a plurality of high-speed I/O signal lines, which may be electrically coupled to solder balls in solder ball array 128. When heated during assembly, the solder balls may melt, creating solid and secure bonds between the ASIC chip 124 and a PCB 134 underneath BGA package 120.

According to some aspects of the instant disclosure, solder ball array 128 may include a set of solder balls arranged in a hexagonal pattern. The set of solder balls may include at least one pair of signal balls (e.g., balls 130 and 132) that are coupled to a pair of differential inputs or outputs on ASIC chip 124. To avoid introducing timing skews in the escape routing paths, signal balls of a differential signal pair are selected to be located in non-adjacent rows (or columns) of the hexagonal pattern. In the example shown in FIG. 1B, signal balls 130 and 132 are in alternate rows (or columns) of the hexagonal patterns. More specifically, signal balls 130 and 132 may be on alternate vertices of a hexagon, forming a diagonal of the hexagon. Moreover, signal balls 130 and 132 may be aligned parallel to an adjacent edge of BGA package 120.

The pair of signal balls 130 and 132 may be coupled to a pair of differential traces 136 and 138 via solder pads 140 and 142, respectively, on PCB 134, facilitating electrical coupling between differential signal traces 136 and 138 and the differential inputs or outputs on ASIC chip 124. For simplicity of illustration, via pads are not shown in the drawing. The differential signal traces may escape from underneath BGA package 120 to couple to other components (not shown in FIG. 1B) on PCB 134. More specifically, the differential signal traces may escape from an adjacent edge parallel to the pair of signal balls.

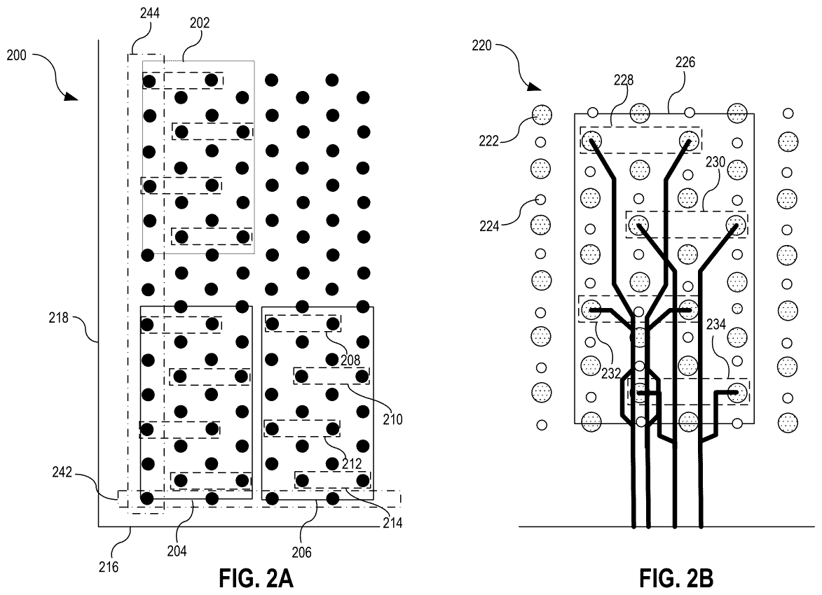

A BGA-packaged device (e.g., a switch ASIC or network interface controller) typically incorporates multiple high-speed I/O ports, each comprising numerous signal lanes. FIG. 2A shows the partial view of an example BGA-packaged device with multiple ports, according to one aspect of the instant disclosure. As illustrated in FIG. 2A, a BGA-packaged device 200 may include a plurality of I/O ports, with the I/O signal paths of each port coupled to solder balls positioned in corresponding different regions in the BGA array, such as regions 202, 204, and 206. These regions are strategically positioned near the edges of BGA-packaged device 200 to facilitate optimized PCB trace escape routing.

In this example, each port may have four lanes, i.e., four differential I/O signal pairs. For example, region 206 includes signal ball pairs 208, 210, 212, and 214. Note that to reduce noise and crosstalk, each signal ball may be surrounded by six ground balls (i.e., solder balls coupled to the ground plane). This arrangement means that adjacent signal ball pairs may be separated by at least two rows of solder balls. FIG. 2A shows an example arrangement of multiple signal ball pairs with minimal separation. In this example, adjacent signal ball pairs (e.g., pairs 208 and 210) are staggered and separated by two rows of solder balls.

FIG. 2B illustrates the partial view of an example printed circuit board (PCB) for mounting the BGA-packaged device, according to one aspect of the instant disclosure. In FIG. 2B, the top layer of PCB 220 may include a plurality of solder pads (e.g., solder pad 222) for mounting a BGA-packaged device. More specifically, the solder pads may be arranged in a pattern corresponding to the ball pattern of the to-be-mounted device. PCB 220 may also include a plurality of vias (e.g., via 224) that can facilitate isolation of the signals.

In the example shown in FIG. 2B, solder pads in region 226 correspond directly to the solder balls in region 206 of FIG. 2A. When mounted on PCB 210, the solder balls in region 206 are electrically and mechanically coupled to their corresponding pads in region 226. For clarity, both the solder ball array (FIG. 2A) and solder pad array (FIG. 2B) are illustrated in top-down PCB views (i.e., viewing from the top of the PCB) to show their alignment.

FIG. 2B shows signal pad pairs 228, 230, 232, and 234 corresponding to signal ball pairs 208, 210, 212, and 214 shown in FIG. 2A, respectively. FIG. 2B also shows examples of escape routing paths. For simplicity of illustration, the signal traces escaping the BGA-package device are shown on the top layer of PCB 220. In practice, the signal traces may be routed on different layers of PCB 220 and may be coupled to the signal pads through the vias. The connections between the signal pads (i.e., solder pads coupled to signal traces) and the vias are not shown in FIG. 2B.

In the example shown in FIGS. 2A-2B, the signal ball pairs are horizontally oriented, with escape traces exiting through the horizontal edge 216 of device 200. No signal trace exits the vertical edge 218. In a practical high-density design with many signal traces, it may be desirable to allow signal traces to escape from multiple edges in different directions. However, when implemented on a square or rectangular package, the hexagonal grid pattern lacks horizontal and vertical symmetry, making it difficult to route escape traces on different edges.

As can be seen in FIG. 2A, a continuous hexagonal grid pattern can include two types of boundaries: staggered (e.g., the horizontal boundary 242 of the ball array) and non-staggered (e.g., the vertical boundary 244 of the ball array). Adjacent solder balls on the staggered boundary are on alternate vertices of a hexagon, whereas adjacent solder balls on the non-staggered boundary are on adjacent vertices of a hexagon. Therefore, the staggered boundary provides more space for escape routing than the non-staggered boundary, and it is preferable to select signal ball pairs that are parallel to the staggered boundary.

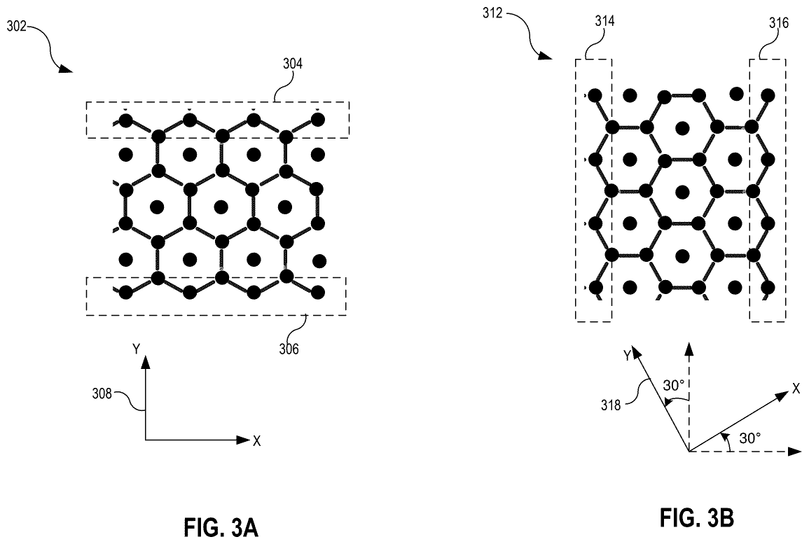

One may rotate a hexagonal pattern to change the orientation of the staggered or non-stagger boundary. FIGS. 3A and 3B illustrate the relative orientations of hexagonal solder ball arrays along adjacent edges of a square/rectangular BGA package, according to one aspect of the instant disclosure. FIG. 3A shows an example hexagonal array 302 with its staggered boundaries in the horizontal direction, such as boundaries 304 and 306. A coordinate system 308 is included in FIG. 3A, with the Y-axis aligned to the longest diagonal of the hexagons to define the array's geometric reference frame.

FIG. 3B shows an example hexagonal array 312 with its staggered boundaries in the vertical direction, such as boundaries 314 and 316. FIG. 3B also shows a coordinate system 318, with its Y-axis aligned to the longest diagonal of the hexagons in array 312. The 30° rotation between coordinate systems 308 (FIGS. 3A) and 316 indicates that array 312 can be generated by rotating array 302 by 30° (either clockwise or counter-clockwise). Leveraging the hexagons'rotational symmetry, equivalent configurations may also be achieved through rotations of multiples of 30° (e.g., 60° or 90°).

To allow signal traces to escape from all edges of a BGA package, according to some aspects, the solder balls of a BGA package may be arranged into multiple, non-continuous hexagonal arrays oriented in ways that every boundary of the BGA array can be staggered to facilitate the exit of the signal traces.

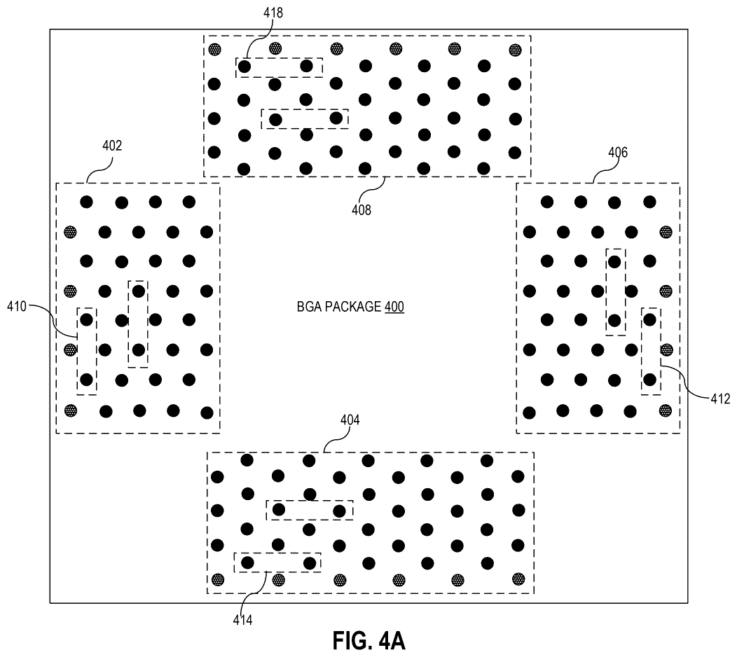

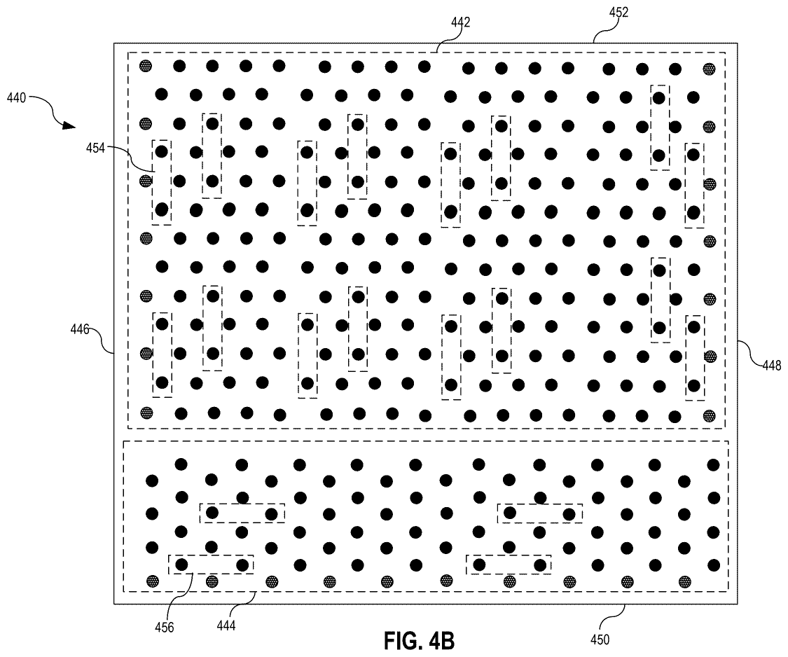

FIG. 4A illustrates an example solder ball arrangement for a BGA package, according to one aspect of the instant application. In FIG. 4A, BGA package 400 includes four sets of solder balls positioned near its four edges. Each set of solder balls may be arranged into a continuous hexagonal array with a specific orientation, such as arrays 402, 404, 406, and 408. Each hexagonal array is oriented such that the outermost row or column near the package edge is staggered (i.e., adjacent balls are on alternate vertices of a hexagon). For illustration purposes, solder balls in the outermost row or column of each solder ball array are shown as circles with shaded patterns to distinguish them from the interior solder balls, which are shown as solid circles.

Hexagonal arrays adjacent to opposite edges have the same orientation. For example, hexagonal arrays 402 and 406 adjacent the opposite vertical edges of package 400 have the same orientation, and hexagonal arrays 404 and 408 adjacent the opposite horizontal edges have the same orientation (which may be rotated 90 degrees from the orientation of arrays 402 and 406). The signal ball pairs in each array are arranged parallel to the adjacent edge. For example, signal ball pairs 410 and 412 in arrays 402 and 406, respectively, are parallel to the vertical edge of package 400, and signal ball pairs 414 and 418 in arrays 404 and 408, respectively, are parallel to the horizontal edge.

FIG. 4A demonstrates a BGA package configuration allowing differential signal trace to escape from all four edges. Alternative implementations may support two-or three-edge escape routing (where the differential signal traces escape from two or three edges of the BGA package) by modifying ball arrangements. In such cases, the arrangement of the solder balls may be different from the one shown in FIG. 4A to accommodate specific routing needs. For example, the boundary of solder balls near a particular edge may be non-staggered.

FIG. 4B illustrates an example solder ball arrangement for a BGA package, according to one aspect of the instant application. In FIG. 4B, the solder balls of BGA package 440 are organized into two sets: a set 442 with its staggered boundary along the two vertical edges of BGA package 440 (i.e., edge 446 and 448) and a set 444 with its staggered boundary along the bottom horizontal edge (i.e., edge 450). This arrangement allows escape routing path to exit from edges 446, 448, and 450 but not from the top horizontal edge 452. FIG. 4B also shows the designation of the signal ball pairs, such as pair 454 (vertically arranged in parallel to vertical edge 446) and pair 456 (horizontally arranged in parallel to horizontal edge 450).

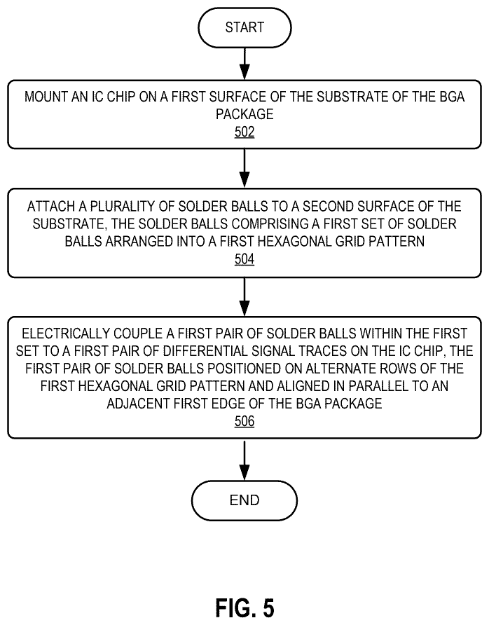

FIG. 5 illustrates an example fabrication process of a BGA package, according to one aspect of the instant application. Although the example process in FIG. 5 shows a specific order, the methods are not limited to such an order. In one or more aspects, one or more of the steps in FIG. 5 may be repeated and/or performed in a different order. Accordingly, the specific arrangement of steps shown in FIG. 5 should not be construed as limiting the scope of this disclosure.

During fabrication, an IC chip may be mounted to a first surface of the substrate of the BGA package (operation 502). The IC chip may be a high-speed switch ASIC or a high-speed NIC and may include a plurality of differential I/O signal traces. The substrate may be made of various types of material, such as plastic, resin, ceramic, or other dielectric composites suitable for high-frequency applications. The IC chip may be attached to the top surface of the substrate via adhesives.

A plurality of solder balls may be attached to a second surface of the substrate, the solder balls comprising a first subset of solder balls arranged into a first hexagonal grid pattern (operation 504). The bottom surface of the substrate may include a plurality of BGA pads arranged into the desired formation (e.g., a hexagonal grid). The solder balls may be made of tin-lead or lead-free alloy. Attaching the solder balls may include the step of heating the substrate in a controlled environment, causing the solder balls to melt and form a metallurgical bond with the BGA pads. The plurality of solder balls may include a second subset arranged into a second hexagonal grid pattern. The two hexagonal grids may be rotationally offset by 30° relative to each other.

A first pair of solder balls within the first set may be electrically coupled to a first pair of differential signal traces on the IC chip, the first pair of solder balls positioned on alternate rows of the first hexagonal grid pattern and aligned in parallel to an adjacent edge of the BGA package (operation 506). Moreover, a second pair of solder balls within the second subset may be electrically coupled to a second pair of differential signals on the IC chip.

In general, the disclosure provides a systematic approach for signal ball selection and edge optimization to eliminate the inherent skew in differential signal pairs. A pair of BGA balls with a substantially equal distance (with a variation of less than 100 μm) to the edge of the BGA package may be selected for a differential signal pair, allowing equal-length escape routing. The pair of signal balls may be positioned on alternate rows within the hexagon lattice and be aligned in parallel to the escaping edge of the package. A typical BGA package with a hexagonal pattern has two edge patterns: a staggered edge and a non-staggered edge. Due to the space constraint of the routing channels, high-speed IO traces typically escape from the staggered edge. For a large package that may require signal traces to escape from all edges, BGA balls near the non-staggered edge may be rearranged (e.g., by rotating 30 degrees) to convert it into a staggered edge.

One aspect of the instant disclosure provides a ball grid array for an integrated circuit (IC) package. The ball grid array may include a first subset of solder balls, arranged in a first hexagonal grid pattern, comprising at least a first pair of signal balls to couple to a first pair of differential signal traces on a printed circuit board. The first pair of signal balls may be positioned in alternate rows that are separated by a row of solder balls of the first hexagonal grid pattern and aligned in parallel to an adjacent first edge of the IC package, via which the first pair of differential signal traces escape the IC package with substantially equal trace lengths.

In a variation on this aspect, the ball grid array may further include a second subset of solder balls arranged in a second hexagonal grid pattern, and orientations of the first and second hexagonal grid patterns may be rotationally offset by 30° relative to each other.

In a further variation, the second subset of solder balls comprises at least a second pair of signal balls to couple to a second pair of differential signal traces on the printed circuit board.

In a further variation, the second pair of signal balls may be positioned in alternate rows of the second hexagonal grid pattern and aligned in parallel to a second edge of the IC package adjacent to the second subset of solder balls.

In a further variation, the IC package may be shaped as a rectangle, and the first and second edges may be adjacent to each other.

In a further variation, the ball grid array may further include first and second boundary lines corresponding, respectively, to the first and second edges. Adjacent solder balls on each boundary line may be positioned on non-adjacent vertices separated by one vertex of a hexagon.

In a variation on this aspect, the IC package may include one or more high-speed input-output (IO) interfaces, and the first pair of signal balls may carry a high-speed IO signal.

One aspect of the instant disclosure provides a circuitry system. The system may include an integrated circuit (IC) chip, a substrate positioned under the IC chip, and a plurality of solder balls positioned under the substrate. The plurality of solder balls may include a first subset of solder balls, arranged in a first hexagonal grid pattern, comprising at least a first pair of signal balls electrically coupled to a first pair of differential signal traces on the IC chip. The first pair of signal balls may be positioned in alternate rows that are separated by a row of solder balls of the first hexagonal grid pattern and aligned in parallel to an adjacent first edge of the substrate.

One aspect of the instant disclosure provides a method for fabricating a ball grid array package. The fabrication method may includemounting an integrated circuit (IC) chip on a first surface of a substrate, attaching a plurality of solder balls to a second surface on the substrate, the plurality of solder balls comprising a first subset of solder balls arranged in a first hexagonal grid pattern, and electrically coupling a first pair of solder balls within the first subset to a first pair of differential signal traces on the IC chip. The first pair of solder balls may be positioned in alternate rows that are separated by a row of solder balls of the first hexagonal grid pattern and aligned in parallel to an adjacent first edge of the ball grid array package.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium.

The methods and processes described above can be included in hardware modules or apparatuses. The hardware modules or apparatus can include, but are not limited to, application-specific integrated circuit (ASIC) chips, field-programmable gate arrays (FPGAs), dedicated or shared processors that execute a particular software module or a piece of code at a particular time, and other programmable-logic devices now known or later developed. When the hardware modules or apparatus are activated, they perform the methods and processes included within them.

The foregoing description is presented to enable any person skilled in the art to make and use the aspects and examples and is provided in the context of a particular application and its requirements. Various modifications to the disclosed aspects will be readily apparent to those skilled in the art, and the general principles defined herein may be applied to other aspects and applications without departing from the spirit and scope of the present disclosure. Thus, the aspects described herein are not limited to the aspects shown but are to be accorded the widest scope consistent with the principles and features disclosed herein.

Furthermore, the foregoing descriptions of aspects have been presented for purposes of illustration and description only. They are not intended to be exhaustive or to limit the aspects described herein to the forms disclosed. Accordingly, many modifications and variations will be apparent to practitioners skilled in the art. Additionally, the above disclosure is not intended to limit the aspects described herein. The scope of the aspects described herein is defined by the appended claims.

What is claimed is:

1. A ball grid array for an integrated circuit (IC) package, the ball grid array comprising:
a first subset of solder balls, arranged in a first hexagonal grid pattern, comprising at least a first pair of signal balls to couple to a first pair of differential signal traces on a printed circuit board;
the first pair of signal balls positioned in alternate rows that are separated by a row of solder balls of the first hexagonal grid pattern and aligned in parallel to an adjacent first edge of the IC package, via which the first pair of differential signal traces escape the IC package with substantially equal trace lengths.

2. The ball grid array of claim 1, further comprising a second subset of solder balls arranged in a second hexagonal grid pattern, and wherein orientations of the first and second hexagonal grid patterns are rotationally offset by 30° relative to each other.

3. The ball grid array of claim 2, wherein the second subset of solder balls comprises at least a second pair of signal balls to couple to a second pair of differential signal traces on the printed circuit board.

4. The ball grid array of claim 3, wherein the second pair of signal balls are positioned in alternate rows of the second hexagonal grid pattern and aligned in parallel to a second edge of the IC package adjacent to the second subset of solder balls.

5. The ball grid array of claim 4, wherein the IC package is shaped as a rectangle, and wherein the first and second edges are adjacent to each other.

6. The ball grid array of claim 5, further comprising first and second boundaries corresponding, respectively, to the first and second edges, wherein adjacent solder balls on each boundary are positioned on non-adjacent vertices separated by one vertex of a hexagon.

7. The ball grid array of claim 1, wherein the IC package comprises one or more high-speed input-output (IO) interfaces, and wherein the first pair of signal balls is to carry a high-speed IO signal.

8. A circuitry system, the system comprising:
an integrated circuit (IC) chip;
a substrate positioned under the IC chip; and
a plurality of solder balls positioned under the substrate;
the plurality of solder balls comprising a first subset of solder balls, arranged in a first hexagonal grid pattern, comprising at least a first pair of signal balls electrically coupled to a first pair of differential signal traces on the IC chip;
the first pair of signal balls positioned in alternate rows that are separated by a row of solder balls of the first hexagonal grid pattern and aligned in parallel to an adjacent first edge of the substrate.

9. The circuitry system of claim 8, wherein the plurality of solder balls further comprise a second subset of solder balls arranged in a second hexagonal grid pattern, and wherein orientations of the first and second hexagonal grid patterns are rotationally offset by 30° relative to each other.

10. The circuitry system of claim 9, wherein the second subset of solder balls comprises at least a second pair of signal balls electrically coupled to a second pair of differential signal traces on the IC chip.

11. The circuitry system of claim 10, wherein the second pair of signal balls are positioned in alternate rows of the second hexagonal grid pattern and aligned in parallel to a second edge of the substrate.

12. The circuitry system of claim 11, wherein the substrate is shaped as a rectangle, and wherein the first and second edges are adjacent to each other.

13. The circuitry system of claim 12, wherein the plurality of solder balls further comprises first and second boundaries corresponding, respectively, to the first and second edges, wherein adjacent solder balls on each boundary are positioned on non-adjacent vertices separated by one vertex of a hexagon.

14. The circuitry system of claim 8, wherein the IC chip comprises one or more high-speed input-output (IO) interfaces, and wherein the first pair of differential signals comprises a high-speed IO signal.

15. The circuitry system of claim 8, wherein the first pair of signal balls are coupled to a first pair of differential traces on a printed circuit board, and wherein the first pair of differential traces are to escape the circuitry system via the first edge with substantially equal trace lengths.

16. A method for fabricating a ball grid array package, comprising:
mounting an integrated circuit (IC) chip on a first surface of a substrate;
attaching a plurality of solder balls to a second surface on the substrate, the plurality of solder balls comprising a first subset of solder balls arranged in a first hexagonal grid pattern; and
electrically coupling a first pair of solder balls within the first subset to a first pair of differential signal traces on the IC chip, the first pair of solder balls positioned in alternate rows that are separated by a row of solder balls of the first hexagonal grid pattern and aligned in parallel to an adjacent first edge of the ball grid array package.

17. The method of claim 16, wherein the plurality of solder balls further comprise a second subset of solder balls arranged in a second hexagonal grid pattern, and wherein orientations of the first and second hexagonal grid patterns are rotationally offset by 30° relative to each other.

18. The method of claim 17, further comprising electrically coupling a second pair of solder balls within the second subset to a second pair of differential signal traces on the IC chip, wherein the second pair of solder balls are positioned in alternate rows of the second hexagonal pattern and aligned in parallel to a second edge of the ball grid array package.

19. The method of claim 18, wherein the ball grid array package is shaped as a rectangle, and wherein the first and second edges are adjacent to each other.

20. The method of claim 19, wherein the plurality of solder balls further comprises first and second boundaries corresponding, respectively, to the first and second edges, wherein adjacent solder balls on each boundary are positioned on non-adjacent vertices separated by one vertex of a hexagon.
